(19) United States
(12) Patent Application Publication
(10) Pub. No.: US 2005/0218499 A1
(43) Pub. Date: Oct. 6, 2005

(54) Method for manufacturing leadless semiconductor packages

(75) Inventors: Chi-Wen Chang, Kaohsiung City (TW); Chao-Ming Tseng, Ciaolou Township (TW)

Correspondence Address: TROXELL LAW OFFICE PLLC, SUITE 1404, 5205 LEESBURG PIKE, FALLS CHURCH, VA, 22041, US

(73) Assignee: Advanced Semiconductor Engineering, Inc.

(21) Appl. No.: 11/092,876

(22) Filed: Mar. 30, 2005

(30) Foreign Application Priority Data
Mar. 31, 2004 (TW) 093108966

(51) Int. Cl. H01L 23/48; H01L 21/44

(52) U.S. Cl. 257/690; 438/124; 438/107; 257/781

(57) ABSTRACT

A method for manufacturing a plurality of leadless semiconductor packages is disclosed. A provided metal carrier has a plurality of packaging units with contact pads and a plurality of separating streets between the packaging units. A plurality of chips are disposed on the corresponding packaging units of the metal carrier and are electrically connected to the contact pads. A plurality of encapsulants are formed on the corresponding packaging units to encapsulate the chips but exposing the separating streets. After the metal carrier is etched away, the encapsulants connected by mold runner bars can be easily separated without sawing or punching.

### FIELD OF THE INVENTION

The present invention relates to the manufacturing of semiconductor packages, and more particularly to a method for manufacturing leadless semiconductor packages.

### BACKGROUND OF THE INVENTION

It is well known in semiconductor packaging, semiconductor chips are disposed on a leadframe. After electrical connection and encapsulation, the outer leads of the leadframe will be exposed and extend from the sides of the encapsulant for electrical connection to a printed circuit board. For reducing the footprint of the semiconductor packages, a leadless semiconductor package is developed whose inner leads or contact pads are exposed from bottom of the encapsulant, such as Quad Flat Non-Leaded package (QFN), and Bump Chip Carrier package (BCC).

R.O.C. Taiwan Patent publication No. 461,057 discloses a QFN package and its method. A leadless leadframe is provided to carry a plurality of chips. During the assembly process, the inner leads of the leadframe are connected to its frame body in the sawing lines. After die attachments and electrical connections, an encapsulant is formed over the chips, the inner leads, and the sawing lines. During singulation, the encapsulant is sawed along the sawing lines to form a plurality of individual QFN packages. Another singulation method is punching. Accordingly, the inner leads have cutting surfaces exposed on the sides of the singulated encapsulants, that will reduce the adhesion between the inner leads and the singulated encapsulants, and increase the electrical interference. For high lead count semiconductor packages, the inner leads for wire-bonding connection are normally designed in a staggered manner. Because the inner leads should connect to the frame body of the leadframe, it is difficult to arrange the inner leads in fine pitch. This makes the design of the inner lead layout become more complicated and difficult.

A conventional method for manufacturing leadless BCC packages is revealed in U.S. Pat. No. 6,573,121. Please refer to FIG. 1, a conventional metal carrier 10 has an upper surface 11, which includes an encapsulating matrix 12 with a plurality of sawing lines 13. As shown in FIG. 2, a plurality of bump pads 21 and a plurality of die pads 22 are formed on the upper surface 11 of the metal carrier 10 by plating. The back surfaces 32 of the chips 30 are attached to the corresponding die pads 22, and a plurality of bonding wires 40 connect the bonding pads 33 on the active surfaces 31 of the chips 30 to the bump pads 21. A square encapsulant 50 encapsulates the encapsulating matrix 12 including the sawing lines 13 and the chips 30. As shown in FIG. 3, after etching away the metal carrier 10, the bump pads 21 and the die pads 22 are exposed from the bottom surface 51 of the encapsulant 50. Then, the encapsulant 50 is singulated by sawing along the sawing lines 13 to form a plurality of individual BCC packages. Therefore, from the conventional BCC assembly processes, the sawing singulation of the encapsulant 50 is a necessary step that cannot be eliminated. However, the alignment step before singulation is very critical as well.

### SUMMARY OF THE INVENTION

A main purpose of the present invention is to provide a method for manufacturing a plurality of leadless semiconductor packages. A metal carrier has a plurality of packaging units and a plurality of separating streets between the packaging units, which are defined on its upper surface. After die attachments and electrical connections, a plurality of encapsulants are formed on the corresponding packaging units but exposing the separating streets. By etching away the metal carriers, the encapsulants can be easily separated into the individual packages. This is done in place of punching or sawing method, moreover, the undersides of the contact pads are exposed from the encapsulants. The contact pads can be arranged in a staggered manner without extending to sides of the encapsulants.

A second purpose of the present invention is to provide a method for manufacturing a plurality of leadless semiconductor packages. A plurality of separating streets between the packaging units are defined in a metal carrier. A plurality of encapsulants are formed on the corresponding packaging units but exposing the separating streets. Using an anti-etching component connecting the encapsulants together, the metal carrier can be etched away to singulate the encapsulants. The anti-etching component may be a mold runner bar, an adhesion tape, or a vessel. Therefore, the encapsulants can be easily separated without sawing or punching.

A third purpose of the present invention is to provide a method for manufacturing a plurality of leadless semiconductor packages. The separating streets between the packaging units of the metal carrier are exposed from a plurality of individual encapsulants for forming a mold runner bar or the other anti-etching component. The mold runner bar connects the individual encapsulants together during the encapsulation. Accordingly, after the metal carrier is etched away, the individual encapsulants can be easily separated without sawing or punching.

According to the present invention, a metal carrier is provided first. A plurality of packaging units and a plurality of separating streets between the packaging units are defined on the upper surface of the metal carrier. Next, a plurality of contact pads are formed within the packaging units by plating. Next, a plurality of chips are disposed on the packaging units. A plurality of bonding wires are used to electrically connect the chips and the contact pads. A plurality of encapsulants are formed on the corresponding packaging units of the metal carrier to encapsulate the chips, but exposing the separating streets. The metal carrier is removed by etching to singulate the encapsulants. Before etching away the metal carrier, the individual packages are connected together through a mold runner bar, an adhesive tape, or a vessel. Since the encapsulants had been singulated after removing the metal carrier, they can be easily separated to form individual packages without sawing or punching.

### DESCRIPTION OF THE DRAWINGS

FIG. 1 is a top view of a metal carrier provided for leadless semiconductor packages by a conventional manufacturing process.

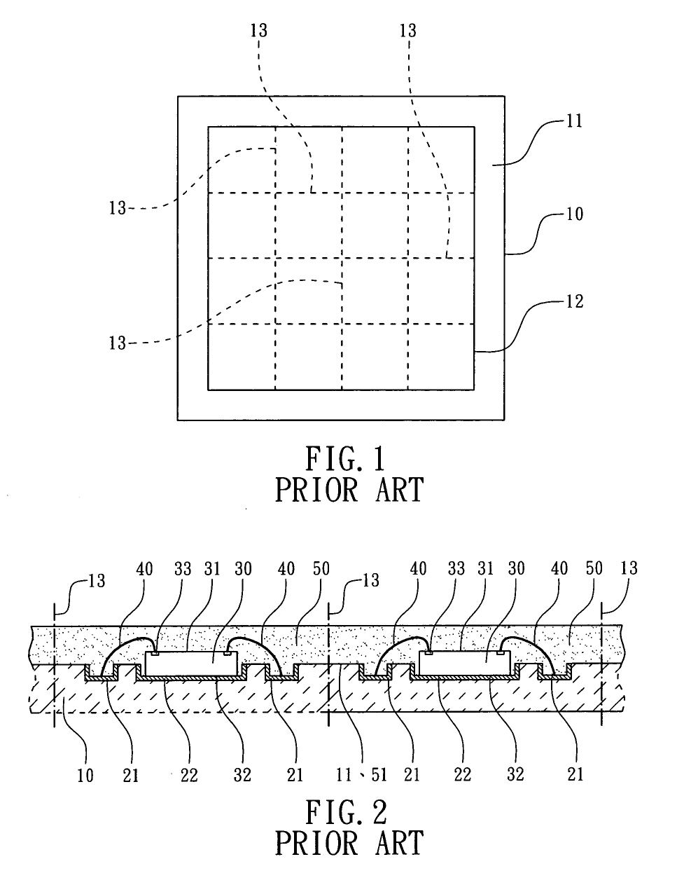

FIG. 2 is a cross-sectional view of the metal carrier with an encapsulant formed during conventional manufacturing process.

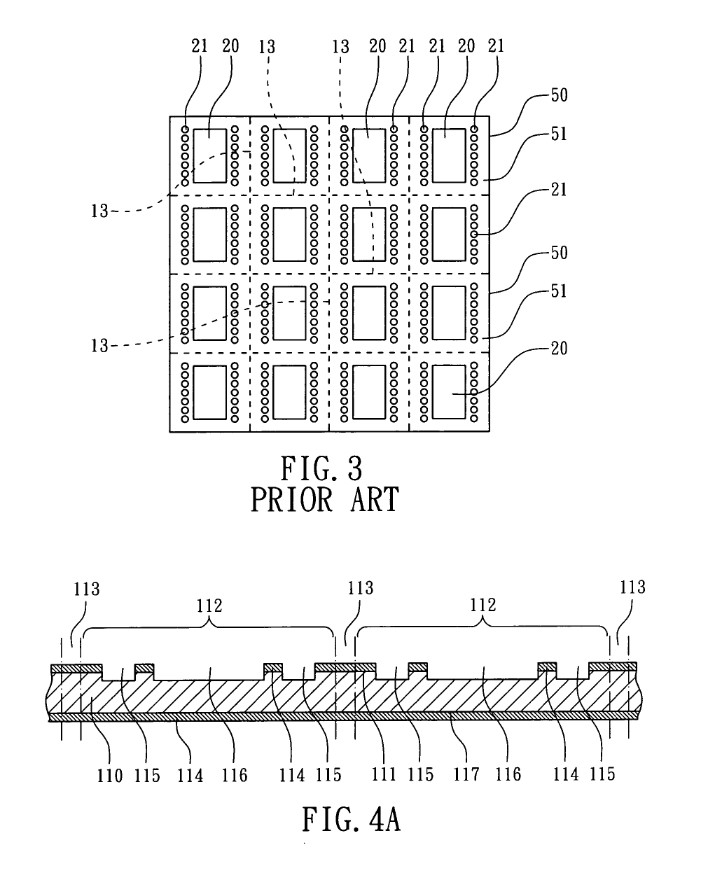

FIG. 3 is a bottom view of the encapsulant after removal of the metal carrier.

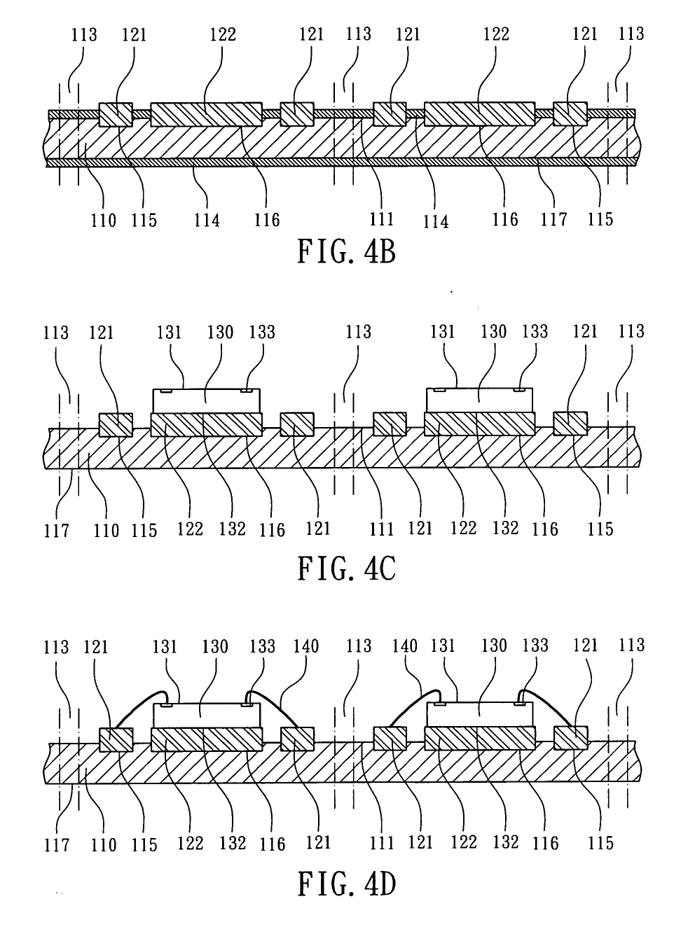

FIGS. 4A to 4F are cross-sectional views of a metal carrier during a preferred process for manufacturing a plurality of leadless semiconductor packages according to the first embodiment of the present invention.

FIG. 5 is a top view of the metal carrier before die attachment according to the first embodiment of the present invention.

FIG. 6 is a bottom view of the encapsulants after removal of the metal carrier according to the first embodiment of the present invention.

FIG. 7 is a cross-sectional view showing a metal carrier with a plurality of encapsulants formed during a manufacturing process according to the second embodiment of the present invention.

FIG. 8 is a cross-sectional view showing the encapsulants after etching away the metal carrier according to the second embodiment of the present invention.

### DETAIL DESCRIPTION OF THE INVENTION

Please refer to the attached drawings, the present invention will be described by means of embodiments below.

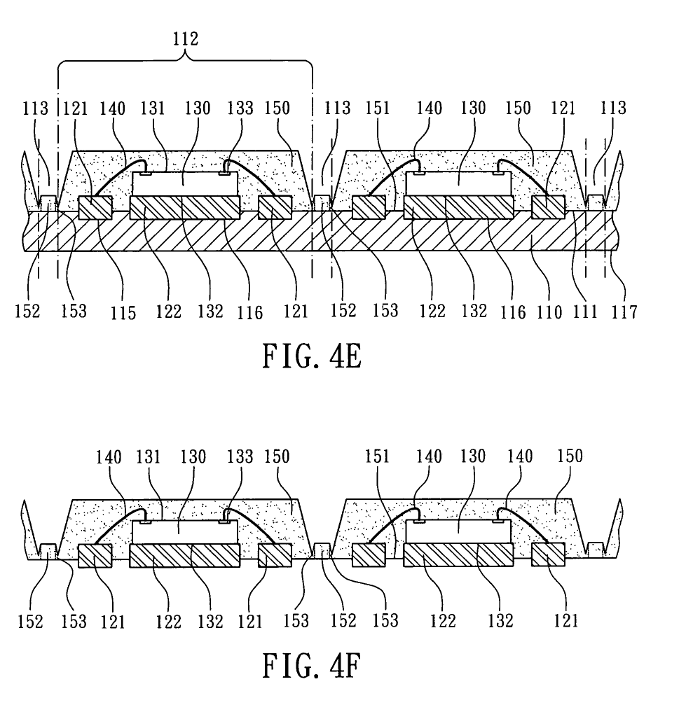

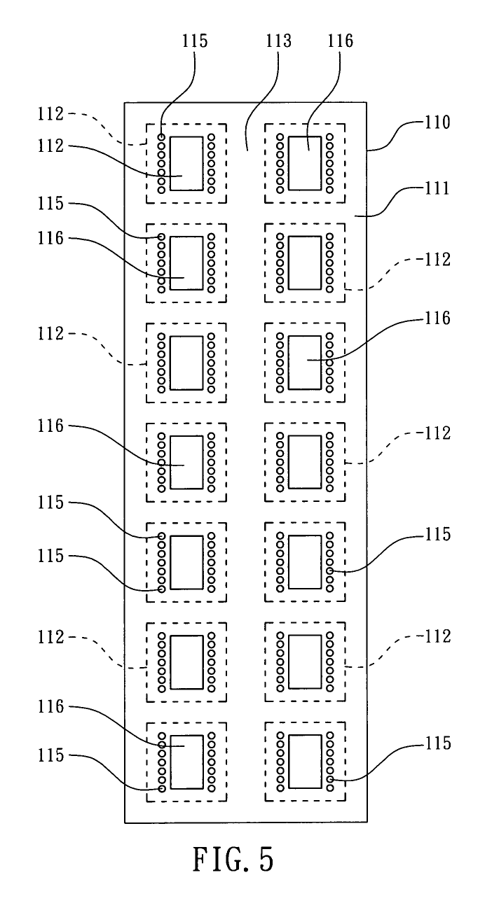

In the first embodiment according to the present invention, a process flow for manufacturing a leadless semiconductor packages is shown from FIGS. 4A to 4F. First, referring to FIG. 4A and FIG. 5, a metal carrier 110 is provided which is a metal foil made of etchable material such as copper, iron, or their alloys. In this embodiment, the metal carrier 110 is a copper foil. A plurality of packaging units 112 and a plurality of separating streets 113 between the packaging units 112 are defined on the upper surface 111 of the metal carrier 110. Therein, the separating streets 113 possess an appropriate width, which can be used for passage of mold runner. Anti-etching photoresists 114 are disposed on the upper surface 111 and on the bottom surface 117 of the metal carrier 110. By using the photolithography, exposed portions of the metal carrier 110 for forming the contact pads 121 and the die pads 122 are defined. Accordingly, a plurality of contact pad cavities 115 and a plurality of die pad cavities 116 are formed within the packaging units 112 in the upper surface 111 by etching. The depths of the contact pad cavities 115 and the die pad cavities 116 range from 0.5 mil to 3 mil. The die pad cavities 116 may be formed as an option, or the portions for forming the die pads 122 can be kept planar without etching.

Then, a plating process is followed. Please refer to FIG. 4B, a plurality of contact pads 121 and a plurality of die pads 122 are formed at the contact pad cavities 115 and at the die pad cavities 116 by plating respectively. The contact pads 121 and the die pads 122 may be consisted of several layers of plated metals, such as gold-palladium-nickel-palladium, gold-palladium, gold-nickel, and gold-chromium-copper-silver. Therein, the most bottom metal layer is anti-etching metal, such as gold or nickel. The contact pads 121 are configured for leadless electrical connections, which are independent of one another without extending to the separating streets 113. Preferably, the contact pads 121 completely fill the contact pad cavities 115 and protrude from the upper surface 111 of the metal carrier 110. The protruding height ranges from 0.5 mil to 3.0 mil.

Then, a die attachment process is followed. Please refer to FIG. 4C, a plurality of chips 130 are deposited on the packaging units 112 of the metal carrier 110, wherein their back surfaces 132 are attached to the corresponding die pads 122, and the contact pads 121 are arranged around the chip 130. Besides, the chips 130 have a plurality of bonding pads 133 on the active surface 131.

Then, an electrical connection process is next. Please refer to FIG. 4D, a plurality of bonding wires 140 or a plurality of bumps are used to electrically connect the bonding pads 133 of the chips 130 and the corresponding contact pads 121.

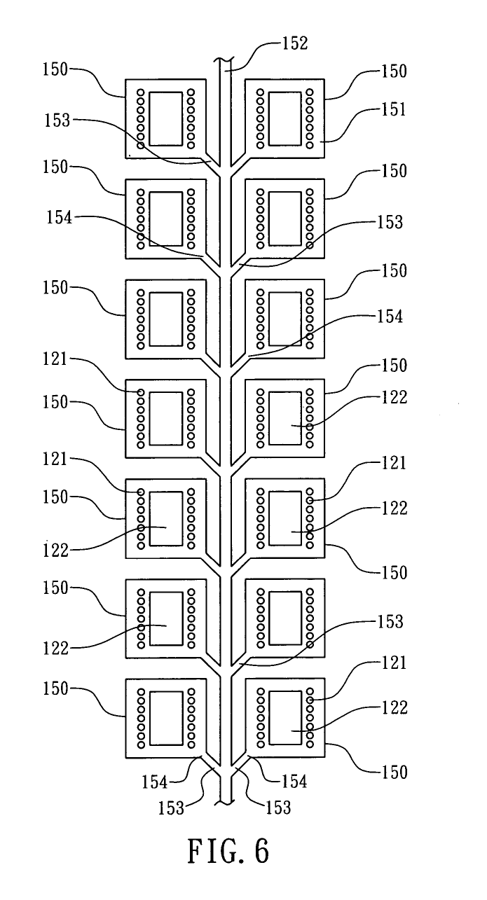

Next, an encapsulation process is followed. Please refer to FIG. 4E, a plurality of encapsulants 150 are formed by molding, printing or dispensing to form on the corresponding packaging units 112 of the metal carrier 110 to encapsulate the chips 130 and the bonding wires 140. The bottom surfaces 151 of the encapsulants 150 further encapsulate the contact pads 121 but exposing the separating streets 113. In this embodiment, the encapsulants 150 are formed by performing a molding process such that each chip 130 and the contact pads 121 are encapsulated respectively within the plurality of encapsulants 150. As shown in FIG. 6A, a mold runner bar 152 is formed on one of the separating streets 113 according to the runners of the molding tool, and is connected to ones of the corners 154 of the encapsulants 150 through a plurality of connecting bars 153.

Then, an etching process is followed. Please refer to FIG. 4F and FIG. 6, the metal carrier 110 is removed, such as using a wet etching or the other method. Moreover, undersides of the contact pads 121 and the die pads 122 are exposed from the bottom surfaces 151 of the encapsulants 150. Since the mold runner bar 152 and the connecting bars 153 are anti-etching, they cannot be etched during the etching of the metal carrier 110. Therefore, the encapsulants 150 are connected together through the connection between the mold runner bar 152 and the connecting bars 153. Moreover, the encapsulants 150 can be easily separated to form individual leadless semiconductor packages without sawing or punching. Moreover, the protrusion height of the contact pads 121 from the bottom surfaces 151 of the encapsulants 150 range from 0.5 mil to 3 mil, which has the benefit of stand-off control. Besides, about half of the contact pads 121 are hidden inside the encapsulants 150 to achieve a better bonding. Comparing to the conventional QFN with planar contact pads, the bumped contact pads 121 have a larger contact possibility for soldering on a PCB. Thus, the leadless semiconductor packages manufactured according the embodiment of the present invention can further enhance the SMT adhesion.

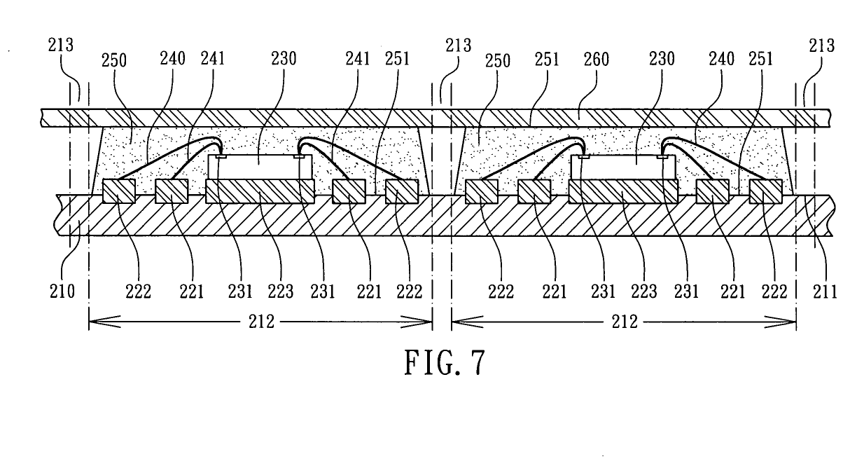

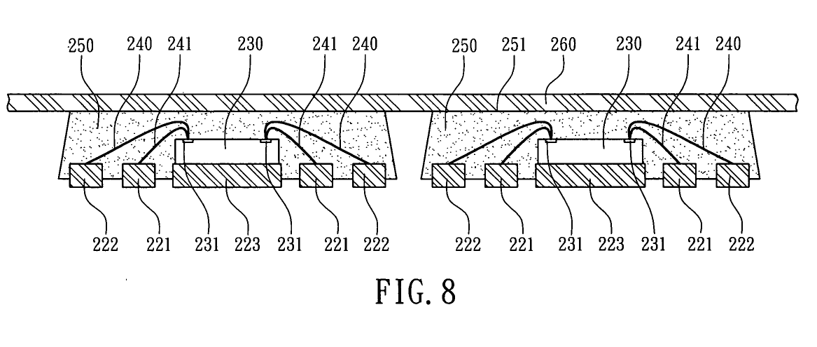

In addition, the second embodiment according to the present invention is shown in FIG. 7 and FIG. 8. A manufacturing process illustrated from the second embodiment also includes providing a metal carrier, plating, die attaching, electrical-connecting, and encapsulating, are the same as the first embodiment, only the step of removing the metal carrier and using other anti-etching component to firmly connect the individual encapsulants together, which will be further explained in details as follows. Please refer to FIG. 7, a metal carrier 210 is provided, which has a plurality of packaging units 212 and a plurality of separating streets 213 between the packaging units 212 defined on its upper surface 211. A plurality of first contact pads 221, a plurality of second contact pads 222, and a die pad 223 are formed within the packaging units 212. Since the first contact pads 221 and the second contact pads 222 are independent of one another without extending to the separating streets 213 and without connecting to leads of leadframe. Therefore, the first and second contact pads 221 and 222 can be arranged in fine pitch and in a staggered manner leading to better layouts and a better electrical performance. Next, a plurality of chips 230 are disposed on the die pads 223 within the packaging units 212. A plurality of bonding wires 240 are used to electrically connect the bonding pads 231 of the chips 230 to the first contact pads 221 and the second contact pads 222. In addition, the ground contact pads of the chips 230 can be electrically connected to the die pad 223 by another bonding wire 241. A plurality of encapsulants 250 are formed on the corresponding packaging units 212 of the metal carrier 210 by dispensing, printing, or molding. Furthermore, the encapsulants 250 encapsulate the chips 230, the bonding wires 240 and 241.

Then, an etching process is followed to remove the metal carrier 210. As shown in FIG. 8, an adhesive tape 260, such as UV tape, vessel or other anti-etching component, is attached to the upper surfaces 252 of the encapsulants 250 to firmly connect the encapsulants 250 during the etching. After removing the metal carrier 250, undersides of the first contact pads 221 and the second contact pads 222 are exposed from the bottom surfaces 251 of the encapsulants 250. Afterward, by peeling the adhesive tape 260, a plurality of individual leadless semiconductor packages with high lead count are separated without sawing or punching.

The above description of embodiments of this invention is intended to be illustrative and not limiting. Other embodiments of this invention will be obvious to those skilled in the art in view of the above disclosure.

1. A method for manufacturing a plurality of leadless semiconductor packages, comprising:
providing a metal carrier having an upper surface with a plurality of packaging units;
forming a plurality of contact pads within the packaging units of the metal carrier;
depositing a plurality of chips on the packaging units of the metal carrier;
electrically connecting the chips to the contact pads;
forming a plurality of encapsulants on the corresponding packaging units of the metal carrier by performing a molding process such that each chip and the contact pads arranged around the chip are encapsulated respectively within the plurality of encapsulants; and
removing the metal carrier, thereby exposing undersides of the contact pads.

2. The method of claim 1, wherein the encapsulants are integrally connected to a mold runner bar.

3. The method of claim 2, wherein the mold runner bar connects to the encapsulants through a plurality of connecting bars.

4. The method of claim 1, wherein the encapsulants are attached to an adhesive tape during removing the metal carrier.

5. The method of claim 1, wherein the encapsulants are disposed inside a vessel during removing the metal carrier.

6. The method of claim 1, wherein the contact pads are formed by the method of plating.

7. The method of claim 1, wherein the metal carrier has a plurality of cavities in the upper surface for accommodating the contact pads.

8. The method of claim 7, wherein the contact pads include a plurality of plating layers filling the cavities and protruding from the upper surface of the metal carrier.

9. The method of claim 1, wherein the contact pads are arranged in a staggered manner.

10. The method of claim 1, wherein the metal carrier is a copper foil, and the step of removing the metal carrier includes wet etching.

11. The method of claim 1, further comprising a step of forming a plurality of die pads within the packaging units during the contact pads are formed.

12. A leadless semiconductor structure comprising:
a plurality of contact pads formed by plating on an etchable metal carrier;
a plurality of chips having a plurality of bonding pads electrically connected to the corresponding contact pads;
a plurality of encapsulants encapsulating the chips, wherein undersides of the contact pads are exposed from the encapsulant; and
an anti-etching component connecting the encapsulants.

13. The structure of claim 12, wherein the anti-etching component is selected from a group consisting of mold runner bar, adhesive tape, and tooling.

14. The structure of claim 12, wherein the contact pads protrude from the encapsulants.

15. The structure of claim 12, wherein the contact pads are made of gold-palladium-nickel-palladium.

16. The structure of claim 12, wherein the contact pads are made of gold-palladium.

17. The structure of claim 12, wherein the contact pads are independent of one another without extending to sides of the encapsulants.

18. The structure of claim 12, wherein the contact pads are arranged in a staggered manner.

19. The structure of claim 12, further comprises a plurality of die pads for disposing the chips.
